(19) United States
(12) Patent Application Publication
(10) Pub. No.: US 2006/0175705 A1
(43) Pub. Date: Aug. 10, 2006

(54) Semiconductor device and method for fabricating the same

(75) Inventors: Makoto Tsutsue, Shiga (JP); Kinya Goto, Tokyo (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/344,102

(22) Filed: Feb. 1, 2006

(30) Foreign Application Priority Data
Feb. 4, 2005 (JP) 2005-028562

(51) Int. Cl. H01L 23/52

(52) U.S. Cl. 257/758

(57) ABSTRACT

A semiconductor device has a first insulating film formed on a substrate and having a first trenched portion, a second insulating film formed on the first insulating film, a third insulating film formed on the second insulating film and having a specific dielectric constant of 3 or less, and a first interconnection formed in the first trenched portion. The second insulating film is made of a compound containing silicon, oxygen, carbon, and nitrogen and the composition ratio of oxygen to silicon in the upper surface of the second insulating film is higher by 5% or more than in the bottom surface of the second insulating film.

### CROSS-REFERENCE TO RELATED APPLICATIONS

The teachings of Japanese Patent Application JP 2005-028562, filed Feb. 4, 2005, are entirely incorporated herein by reference, inclusive of the specification, drawings, and claims.

### BACKGROUND OF THE INVENTION

The present invention relates to a semiconductor device comprising metal interconnections made of copper or the like and an interlayer insulating film with a low dielectric constant and to a method for fabricating the same.

With the recent trends toward the higher integration of a semiconductor integrated circuit, an interconnection pattern has been increased in density and a parasitic capacitance occurring between interconnections has also been increased. Because an increased parasitic capacitance between interconnections causes signal delay, a reduction in the parasitic capacitance between interconnections is an important challenge in a semiconductor integrated circuit of which a high-speed operation is required. To reduce the parasitic capacitance between interconnections, reductions in the specific dielectric constants of insulating films between interconnections and between layers are attempted at present.

As conventional insulating films between interconnections and the like, silicon dioxide (SiO₂) films (with specific dielectric constants of 3.9 to 4.2) have been used in most cases. Some semiconductor integrated circuits have used SiO₂ films containing fluorine (F) (with specific dielectric constants of 3.5 to 3.8) as insulating films between interconnections which have specific dielectric constants lower than those of the conventional SiO₂ films. To further reduce an electric parasitic capacitance between interconnections, a semiconductor device using a low dielectric constant film composed of a carbon-containing silicon oxide (SiOC) film with a specific dielectric constant of 3 or less as an insulating film between interconnections has currently been proposed.

In a semiconductor device using such an SiOC film as an insulating film between interconnections, it is typical that a SiO₂ film is further formed on the SiOC film. This is for the prevention of physical damage to the SiOC film in a CMP step since the SiOC film is low in mechanical strength. This is also for the prevention of the problem encountered when a resist pattern is formed directly on the SiOC film that an ashing process for removing the resist pattern degrades the low dielectric constant film and undesirably increases the dielectric constant.

However, since the adherence of the SiOC film to the SiO₂ film is low, another problem occurs that a mechanical stress exerted during the process of fabricating the semiconductor device (in, e.g., a CMP process) causes delamination of the SiOC film from the SiO₂ film at the interface therebetween.

As a method for preventing the problem of the delamination of the SiOC film from the SiO₂ film at the interface therebetween, there has been known one which modifies the surface of the SiOC film and thereby increases the adherence thereof to the SiO₂ film at the interface therebetween (see, e.g., Japanese Laid-Open Patent Publication No. 2004-253790).

### SUMMARY OF THE INVENTION

However, the delamination of the SiOC film occurs not only at the interface with the SiO₂ film but also at the interface with a metal diffusion preventing film. Since the delamination of the SiOC film from the metal diffusion preventing film at the interface therebetween mostly occurs during wafer dicing or after packaging, it causes a more serious problem.

It is therefore an object of the present invention to solve the conventional problems described above and provide a high-reliability semiconductor device having metal interconnections each covered with a low dielectric constant film, wherein the low dielectric constant film has increased adherence to a metal diffusion preventing film for preventing metal diffusion from the metal interconnections at the interface therebetween and the delamination of the low dielectric constant film from the metal diffusion preventing film is less likely to occur, and a method for fabricating the same.

To attain the object, the semiconductor device according to the present invention has the metal diffusion preventing film in which the uppermost layer is composed of a film having an atomic percent of oxygen higher than that of the lower layer.

Specifically, the semiconductor device according to the present invention assumes a semiconductor device comprising: a first insulating film formed on a substrate and having a first trenched portion; a second insulating film formed on the first insulating film; a third insulating film formed on the second insulating film and having a specific dielectric constant of 3 or less; and a first interconnection formed in the first trenched portion, wherein the second insulating film is made of a compound containing silicon, oxygen, carbon, and nitrogen and a composition ratio of oxygen to silicon is higher by 5% or more in an upper surface of the second insulating film than in a bottom surface of the second insulating film.

In the semiconductor device according to the present invention, the adherence between the second and third insulating films is high so that delamination does not occur between the second and third insulating films when the semiconductor device is fabricated or used actually. As a result, a high-reliability semiconductor device can be implemented.

Preferably, the semiconductor device according to the present invention further comprises: a fourth insulating film formed between the first and second insulating films and made of a compound containing silicon, oxygen, carbon, and nitrogen, wherein the second insulating film is preferably made of a compound in which an atomic percent of oxygen is higher than an atomic percent of nitrogen and the fourth insulating film is preferably made of a compound in which the atomic percent of oxygen is lower than the atomic percent of nitrogen. The arrangement reliably increases the adherence between the second and third insulating films, while allowing the retention of the function of preventing metal diffusion. In addition, the arrangement can prevent the occurrence of a defect in forming the interconnection trench.

In the semiconductor device according to the present invention, the third insulating film is preferably made of carbon-containing silicon oxide (SiOC).

Preferably, the semiconductor device according to the present invention further comprises: a second interconnection made of a conductive material filled in a second trenched portion provided in the third insulating film. In this case, the semiconductor device according to the present invention preferably further comprises: a plug formed to extend through at least the second and third insulating films and provide an electric connection between the first and second interconnections. The arrangement allows the implementation of a high-reliability semiconductor device which is free from signal delay and delamination between the second and third insulating films.

Preferably, the semiconductor device according to the present invention further comprises: a fifth insulating film formed on the third insulating film and protecting the third insulating film. The arrangement can prevent physical damage to the third insulating film and reliably prevent an increase in the dielectric constant of the third insulating film.

A method for fabricating a semiconductor device according to the present invention comprises the steps of: (a) forming a first insulating film on a substrate, forming a first trenched portion in the first insulating film, and then filling a conductive material in the first trenched portion to form a first interconnection; (b) forming, on the first insulating film, a second insulating film made of a compound containing silicon, oxygen, carbon, and nitrogen and covering the first interconnection; (c) forming, in an upper surface of the second insulating film, a surface layer in which a composition ratio of oxygen to silicon is higher by 5% or more than in a bottom surface of the second insulating film; and (d) forming, on the second insulating film, a third insulating film having a specific dielectric constant of 3 or less.

Since the method for fabricating a semiconductor device according to the present invention increases the adherence between the second and third insulating films, it can prevent delamination between the second and third insulating films and allows the fabrication of a high-reliability semiconductor device.

In the method for fabricating a semiconductor device according to the present invention, the third insulating film is preferably made of carbon-containing silicon oxide (SiOC).

In the method for fabricating a semiconductor device according to the present invention, the step (c) is preferably a step of exposing the upper surface of the second insulating film to a plasma of a helium gas or a gas mixture containing helium. The arrangement allows the surface layer in which the composition ratio of oxygen to silicon is higher by 5% or more than in the bottom surface of the second insulating film to be formed reliably in the upper surface of the second insulating film. In this case, the plasma is preferably a plasma of a gas mixture containing at least one of oxygen and carbon dioxide. The arrangement allows the composition ratio of oxygen to be increased reliably in the upper surface of the second insulating film.

In the method for fabricating a semiconductor device according to the present invention, the step (c) is preferably a step of continuously processing the second insulating film without exposing the second insulating film to an ambient atmosphere by using the same chamber as used to form the second insulating film in the step (b). The arrangement also allows the modification of the surface of the second insulating film without causing damage to the second insulating film.

In the method for fabricating a semiconductor device according to the present invention, the step (c) is preferably a step of depositing, on the upper surface of the second insulating film, the surface layer in which the composition ratio of oxygen to silicon is higher by 5% or more than in the bottom surface of the second insulating film. The arrangement also allows reliable formation of the surface layer.

Preferably, the method for fabricating a semiconductor device according to the present invention further comprises the step of: (e) prior to the step (b), forming a fourth insulating film made of a compound containing silicon, oxygen, carbon, and nitrogen on the first insulating film, wherein the second insulating film is preferably made of a compound in which an atomic percent of oxygen is higher than an atomic percent of nitrogen and the fourth insulating film is preferably made of a compound in which the atomic percent of oxygen is lower than the atomic percent of nitrogen. The arrangement can prevent the formation of a defective interconnection trench. In this case, the steps (e) and (b) are preferably performed continuously in the same vacuum chamber.

Preferably, the method for fabricating a semiconductor device according to the present invention further comprises the step of: (f) after the step (d), forming a second trenched portion in an upper portion of the third insulating film and filling a conductive material in the second trenched portion to form a second interconnection. In this case, the step (f) preferably includes the steps of: forming a via hole at a position included in a region of the third insulating film formed with the second trenched portion to expose the first interconnection therethrough; and filling a conductive material in the via hole to form a plug for providing an electric connection between the first and second interconnections. The arrangement allows the metal interconnection to be formed reliably in the third insulating film with a low dielectric constant.

The present invention allows the implementation of a high-reliability semiconductor device having metal interconnections each covered with a low dielectric constant film, wherein the low dielectric constant film has increased adherence to a metal diffusion preventing film for preventing metal diffusion from the metal interconnections at the interface therebetween and the delamination of the low dielectric constant film from the metal diffusion preventing film is less likely to occur, and a method for fabricating the same.

### BRIEF DESCRIPTION OF THE DRAWINGS

FIG. 1 is a cross-sectional view of an interconnection portion in a semiconductor device according to an embodiment of the present invention;

FIGS. 2A to 2D are cross-sectional views illustrating the individual steps of a method for fabricating the semiconductor device according to the embodiment in the order they are performed;

FIG. 3 is a graph showing the relationship between a plasma exposure time and the composition ratio of oxygen in a surface of a film in the method for fabricating the semiconductor device according to the embodiment;

FIG. 4 is a graph showing the relationship between the plasma exposure time and an adherence strength ratio in the method for fabricating the semiconductor device according to the embodiment;

FIG. 5 is graph showing the relationship between the plasma exposure time and the composition ratio of oxygen in the surface of the film in a method for fabricating a semiconductor device according to another example of the embodiment;

FIG. 6 is a cross-sectional view showing an interconnection portion in a semiconductor device according to a variation of the embodiment; and

FIGS. 7A to 7D are cross-sectional views illustrating the individual steps of a method for fabricating the semiconductor device according to the variation in the order they are performed.

### DETAILED DESCRIPTION OF THE INVENTION

### Embodiment 1

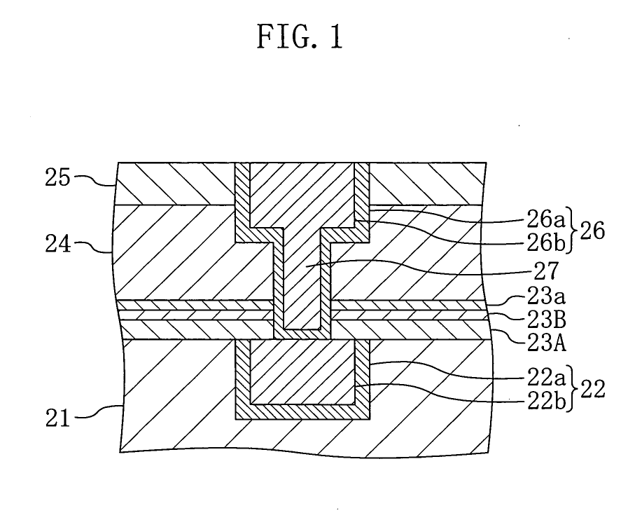

Referring to the drawings, a semiconductor device according to an embodiment of the present invention will be described. FIG. 1 shows the cross-sectional structure of an interconnection portion in the semiconductor device according to the present embodiment. As shown in FIG. 1, a first metal interconnection 22 composed of a barrier metal 22a made of tantalum nitride (TaN) and a conductive film 22b made of copper (Cu) is formed in a first insulating film 21 made of silicon dioxide (SiO₂) and formed on a substrate (not shown) made of Si. On the first insulating film 21, a second insulating film 23A and a third insulating film 23B each made of silicon oxide containing carbon and nitrogen (SiOCN) and functioning as a metal diffusion preventing film are formed successively to cover the first metal interconnection 22.

The second insulating film 23A is made of SiOCN and lower in the atomic percent of oxygen atoms (O) than in the atomic percent of nitrogen atoms (N). The third insulating film 23B is made of SiOCN and higher in the atomic percent of O than in the atomic percent of N. In the present embodiment, the respective atomic percents of individual atoms measured by X-ray photoelectron spectroscopy (XPS) are such that Si=41, O=1, C=36, and N=22 in the second insulating film 23A and that Si=38, O=25, C=36, and N=1 in the third insulating film 23B.

In the upper surface of the third insulating film 23B, a surface layer 23a is formed in which a composition ratio of O to Si (25/38=0.66) is higher by 5% or more than in the inner portion of the third insulating film 23B. The composition ratio of O to Si is a value calculated by dividing the atomic percent of O by the atomic percent of Si.

On the third insulating film 23B, a fourth insulating film 24 made of carbon-containing silicon oxide (SiOC) with a specific dielectric constant of 3 or less and a fifth insulating film 25 made of SiO₂ are formed successively. To increase the adherence between the fourth and fifth insulating films 24 and 25, a SiOC layer having an extremely small film thickness and a high abundance ratio of O may also be provided appropriately at the interface between the fourth and fifth insulating films 24 and 25.

In a trenched portion provided in each of the fourth and fifth insulating films 24 and 25, a second metal interconnection 26 composed of a barrier metal 26a made of TaN and a conductive film 26b made of Cu is formed. The first and second metal interconnections 22 and 26 are electrically connected to each other through a via 27 extending through the second, third, and fourth insulating films 23A, 23B, and 24.

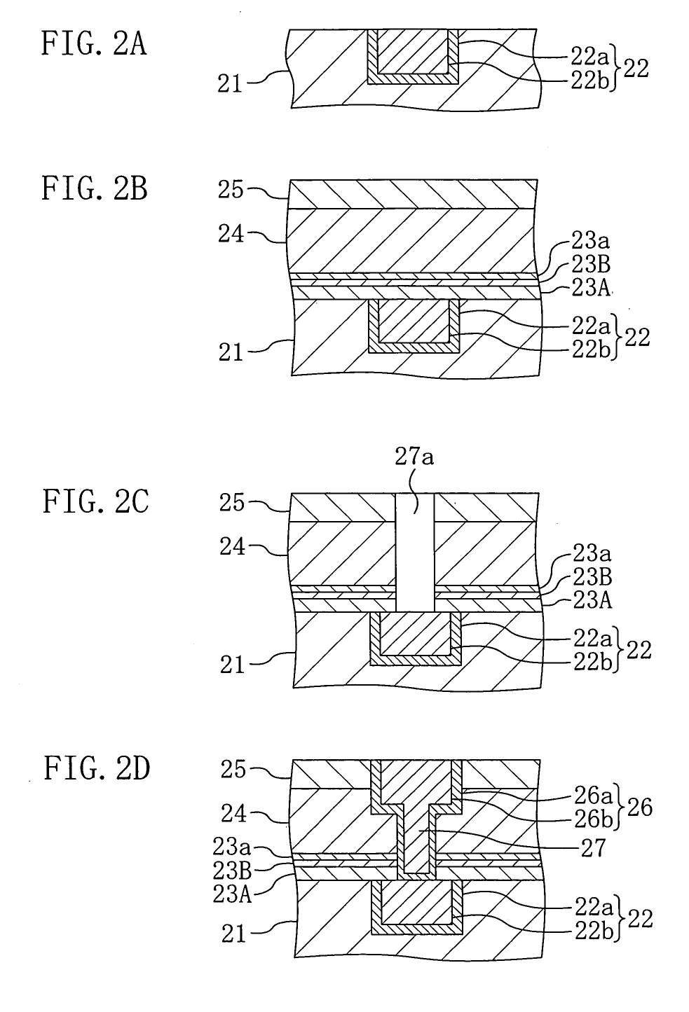

A description will be given next to a method for fabricating the semiconductor device according to the present embodiment. FIGS. 2A to 2D illustrate the cross-sectional states of the interconnection portions in the semiconductor device according to the present embodiment in the individual fabrication steps in the order they are performed;

First, as shown in FIG. 2A, the first insulating film 21 made of SiO₂ is formed on the substrate (not shown) and coated with a resist, which is formed into a pattern for an interconnection trench by lithography. Then, after forming the interconnection trench by dry etching using the pattern as a mask, the resist is removed by ashing so that the interconnection trench is formed in the first insulating film 21. Subsequently, the barrier metal 22a made of TaN is formed by sputtering in the interconnection trench and the conductive film 22b made of Cu is filled therein by electric plating. Thereafter, the unneeded portions of the barrier metal 22a and the conductive film 22b which are protruding out of the interconnection trench are removed by chemical mechanical polishing (CMP) so that the first metal interconnection 22 composed of the barrier metal 22a and the conductive film 22b is formed.

Next, as shown in FIG. 2B, the second and third insulating films 23A and 23B each made of SiOCN are formed successively by chemical vapor deposition (CVD) on the first insulating film 21 to cover the first metal interconnection 22. First, the second insulating film 23A in which the atomic percent of N is higher than the atomic percent of O is formed in a plasma atmosphere using a gas containing at least N. Subsequently, the third insulating film 23B in which the atomic percent of O is higher than the atomic percent of N is formed in a plasma atmosphere using a gas containing at least O. Then, the surface of the third insulating film 23B is exposed to a plasma atmosphere using a helium (He) gas, whereby the surface of the third insulating film 23B is modified and the surface layer 23a in which the composition ratio of O to Si is higher than in the inner portion of the third insulating film 23B is formed.

In the present embodiment, the second insulating film 23A in which the atomic percent of N is higher than that of O and the third insulating film 23B in which the atomic percent of O is higher than that of N are stacked in layers. In the case where a C-containing Si oxide film having therein a Si—O—CH₃ bond and a Si—CH₃ bond is used for the first insulating film formed under the second insulating film, when the first insulating film is damaged by a plasma, the Si—O—CH₃ bond and the Si—CH₃ bond in the C-containing Si oxide film are broken so that bases such as an OH⁻ group and a CH₃⁻ group are formed. Such bases are diffused into the resist via a through hole in a lithographic step so that the concentration of the bases in the resist is increased. This causes faulty development during the formation of a trench pattern using an acrylic chemical amplified resist and the problem of abnormal connection between the first and second metal interconnections. By stacking the third insulating film in which an O concentration is higher than an N concentration on the second insulating film 23A, it becomes possible to prevent the diffusion of the bases and the formation of a defective interconnection trench pattern.

After forming the surface layer 23a by modifying the surface of the third insulating film 23B, the fourth insulating film 24 made of SiOC with a specific dielectric constant of 3 or less is formed by CVD on the third insulating film 23B. Subsequently, the fifth insulating film 25 made of a SiO film is formed also by CVD on the fourth insulating film 24. By exposing the surface of the fourth insulating film 24 to a plasma atmosphere using a gas containing, e.g., O and then depositing the fifth insulating film 25, the adherence between the fourth and fifth insulating films 24 and 25 can be increased.

Then, as shown in FIG. 2C, a resist is coated on the fifth insulating film 25 and formed into a pattern for a via hole by lithography. Thereafter, dry etching and ashing are performed by using the pattern as a mask to form a via hole 27a extending through the second, third, fourth, and fifth insulating films 23A, 23B, 24, and 25.

Next, as shown in FIG. 2D, a resist is coated again on the surface of the fifth insulating film 25 and formed into a pattern for an interconnection trench by lithography. Then, by using the pattern as a mask, dry etching and ashing are performed to form the interconnection trench in each of the fourth and firth insulating films 24 and 25. Thereafter, the barrier metal 26a made of TaN is formed by sputtering in the interconnection trench and then the conductive film 26b made of Cu is formed by electric plating. Subsequently the unneeded portions of the barrier metal 26a and the conductive film 26b which are protruding out of the interconnection trench are removed by CMP so that the second metal interconnection 26 composed of the barrier metal 26a and the conductive film 26b and the via 27 are formed.

A description will be given herein below to the influence of the composition ratio of O to Si in the surface layer 23a of the third insulating film 23B on the adherence between the third and fourth insulating films 23B and 24.

The interface between the third and fourth insulating films 23B and 24 in the structure shown in FIG. 1 is formed specifically as follows. First, the second insulating film 23A in which the atomic percent of N is higher than that of O and the third insulating film 23B in which the atomic percent of O is higher than that of N are deposited successively by CVD. Subsequently, a He gas is supplied at a flow rate of 1500 sccm into the same vacuum chamber as used to deposit the second and third insulating films 23A and 23B to set the internal pressure of the chamber to 500 Pa and the internal temperature thereof to 350° C. A plasma is generated in the chamber by the application of an RF power of 300 W and the third insulating film 23B is exposed to the plasma. This modifies the surface of the third insulating film 23B and forms the surface layer 23a in which the composition ratio of O to Si is higher by 5% or more than in the internal portion of the third insulating film 23B on the third insulating film 23B.

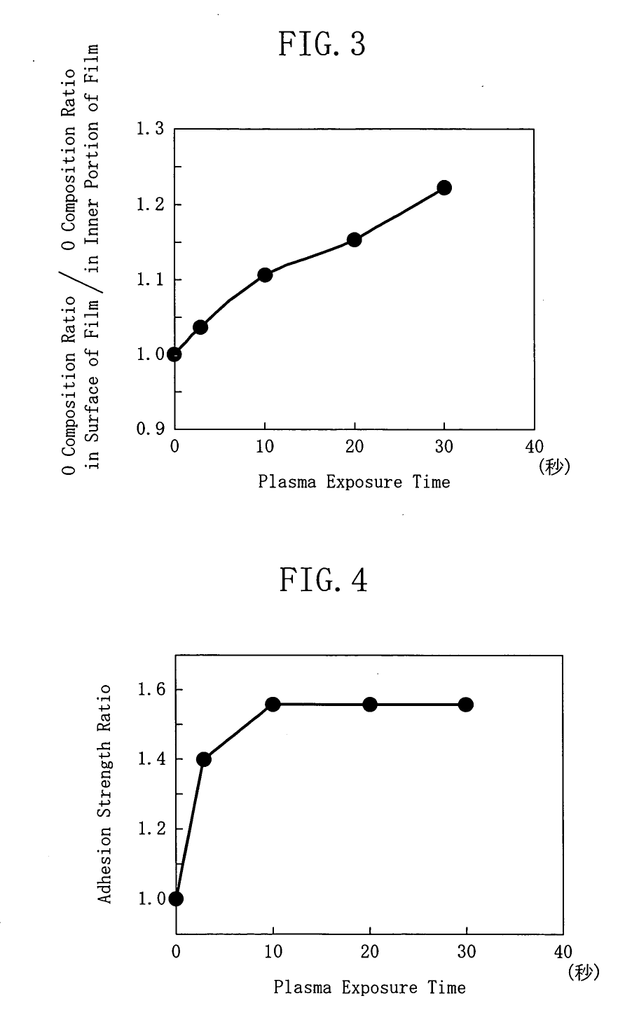

FIG. 3 shows the relationship between a plasma exposure time and an O composition ratio in the surface layer 23A. As the O composition ratio, the value calculated as follows is used herein. After the third insulating film 23B was exposed to the plasma for a specified period, the respective atomic percents of Si, O, C, and N in the surface layer 23a formed in the surface of the third insulating film 23B were measured by XPS. By dividing the obtained atomic percent of O by the obtained atomic percent of Si, the composition ratio of O to Si was calculated. In FIG. 3, the abscissa axis represents the plasma exposure time and the ordinate axis represents the value calculated by dividing the O composition ratio in the surface layer 23b by the O composition ratio in the inner portion of the third insulating film 23B.

As shown in FIG. 3, as the plasma exposure time becomes longer, the modification of the surface of the third insulating film 23B proceeds and the O composition ratio in the surface layer 23a becomes higher.

FIG. 4 shows the relationship between the plasma exposure time and the adherence strength ratio at the interface between the third and fourth insulating films 23B and 24. In FIG. 4, the abscissa axis represents the plasma exposure time and the ordinate axis represents the adherence strength ratio. As the adherence strength ratio, the result of measurement performed by using an mELT (modified Edge Lift Off test) method is used herein. As shown in FIG. 4, the exposure to the plasma for several seconds rapidly increased the adherence strength. After performing the first exposure to the plasma for about 10 seconds, even though second and third exposures to the plasma were further performed for 20 seconds and for 30 seconds, respectively, the adherence strength ratio was held at about 1.55 and did not change greatly.

From the summarized results shown in FIGS. 3 and 4, it is evident that an increase in the O composition ratio in the surface layer 23a formed by modifying the surface of the third insulating film 23B increases the adherence thereof with the fourth insulating film 24. When an exposure to the plasma was performed for a time period of about 10 seconds such that the adherence strength ratio is held constant, the increase ratio of the O composition ratio in the surface layer 23a to that in the inner portion of the third insulating film 23B is about 1.05. Accordingly, it will be understood that, when the O composition ratio in the third insulating film 23B increases by 5% or more, the surface layer 23a resulting from the surface modification is allowed to have a sufficient adherence to the fourth insulating film 24.

To prove the effect, the occurrence of film delamination in an actual situation was examined next. Table 1 shows the relationship between the plasma exposure time and film delamination. In this case, the presence or absence of delamination was observed immediately after the CMP step for polishing away the unneeded portions of the barrier metal 26a and the conductive film 26b shown in FIG. 2D and forming the second metal interconnection 26.

TABLE 1

| Plasma Exposure Time | |
|---|---|
| (seconds) | Delamination |
| 0 | Present |
| 3 | Absent |
| 10 | Absent |
| 20 | Absent |
| 30 | Absent |

As shown in Table 1, when the plasma exposure time was 0 seconds, delamination occurred. However, film delamination was not observed when the exposure time was 3 seconds or longer. This has proved that the present invention can implement a high-reliability semiconductor device since it has increased the adherence between the third and fourth insulating films 23B and 24 and prevent the occurrence of a defect during the fabrication steps for the semiconductor device.

Although the present embodiment has performed the processing in the plasma atmosphere composed of the He gas to modify the surface of the third insulating film 23B and form the surface layer 23a with a high composition ratio of O, the same effects are achievable even when a method which performs exposure to a plasma atmosphere composed of a gas mixture obtained by mixing an O-containing gas such as O₂ or CO₂ with He.

A description will be given herein below to the criterion for determining the composition ratio of O to Si in the surface layer 23a. As has been described above, the composition ratio of O in the surface layer 23a is higher by 5% or more than that of O in the inner portion of the third insulating film 23B. In this case, as the composition ratio of O to Si in the inner portion of the third insulating film 23B, the composition ratio of O to Si in the bottom surface of the third insulating film 23B in contact with the second insulating film 23A is used.

When it is difficult to measure the composition ratio in the bottom surface, the composition ratio of O to Si in the region of the third insulating film 23B where the abundance ratios of the individual atoms have uniform profiles in the direction of depth may also be used instead. In the case where the third insulating film 23B with a thickness of 60 nm was deposited by CVD and then plasma exposure was performed, e.g., the region of the third insulating film 23B corresponding to a depth of about 10 nm to 50 nm from the upper surface thereof was modified in accordance with the plasma exposure time to form the surface layer 23a. Accordingly, the composition ratio of O to Si is constant in the region deeper than the surface layer 23a and therefore the composition ratio of O to Si in the deeper region may be used appropriately as the O composition ratio in the inner portion of the third insulating film 23B.

In the present embodiment, the second insulating film 23A in which the atomic percent of N is higher than that of O and the third insulating film 23B in which the atomic percent O is higher than that of N have been deposited and then the surface of the third insulating film 23B has been modified to form the surface layer 23a. However, it is also possible to use a SiCN film barely containing O as the second insulating film 23A and use a SiOC film barely containing N as the third insulating film 23B.

Instead of exposing the surface of the third insulating film 23B to the plasma, it is also possible to form the third insulating film 23B, deposit a thin film in which the composition ratio of O to Si is higher by 5% or more than in the third insulating film 23B on the third insulating film 23B, and thereby form the surface layer 23B.

Although SiO₂ has been used for the first insulating film 21 and SiOC has been used for the fourth insulating film 24, it is also possible to form each of the first and fourth insulating films 21 and 24 from SiOC provided that each of the insulating films functions as an interlayer insulating film. Another low dielectric constant film such as a porous film may also be used instead.

A description will be given next to the effect achieved by continuously and successively forming the third insulating film 23B and the surface layer 23a in the same chamber without exposing the third insulating film 23B to an ambient atmosphere.

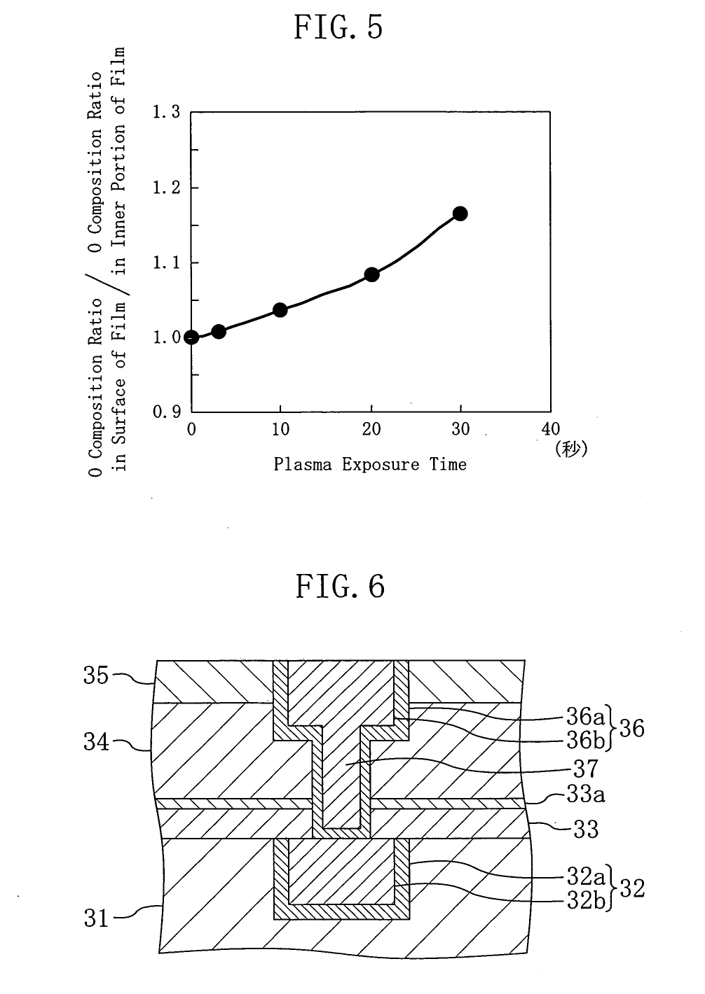

FIG. 5 shows the relationship between the plasma exposure time and the composition ratio of O to Si when the substrate formed with the third insulating film 23B was retrieved from the vacuum chamber, allowed to stand in an ambience at room temperature and atmospheric pressure, reintroduced into the vacuum chamber, and then subjected to plasma exposure. The conditions for the plasma exposure and the method for measuring the O composition ratio used herein are the same as those used when the plasma exposure was performed continuously as shown in FIG. 3. In FIG. 5, the abscissa axis represents the plasma exposure time and the ordinate axis shows the value calculated by dividing the O composition ratio in the surface layer 23a by the O composition ratio in the inner portion of the third insulating film 23B.

As shown in FIG. 5, the O composition ratio increases as the plasma exposure time becomes longer. However, it will be understood that the speed at which the composition ratio of O to Si increases is lower than in FIG. 3. That is, when the third insulating film is exposed to the ambient atmosphere, it is necessary to perform plasma processing in the He plasma atmosphere for a longer time than when the third insulating film is not exposed to the ambient atmosphere. This may be conceivably because, when the third insulating film 23B is formed, retrieved from the vacuum chamber, and exposed to the ambient atmosphere, moisture and a gas in the ambient atmosphere are adsorbed to the surface of the third insulating film 23B so that, at the initial stage of the plasma processing performed by reintroducing the third insulating film 23B into the vacuum chamber, the removal of the adsorbed moisture and gas is performed and, accordingly, the time required to increase the composition ratio of O in the surface of the third insulating film becomes longer.

Exposing the insulating film to the plasma atmosphere for a longer time is undesirable because it leads to increased plasma damage, a higher specific dielectric constant, and the like and thereby causes film degradation. Therefore, the formation of the surface layer 23a is preferably performed continuously after the formation of the third insulating film 23B without exposing the chamber to the ambient atmosphere.

Variation

Referring to the drawings, a semiconductor device according to a variation of the present invention will be described. FIG. 6 shows the cross-sectional structure of interconnection portions in the semiconductor device according to the present variation. As shown in FIG. 6, a first metal interconnection 32 composed of a barrier metal 32a made of tantalum nitride (TaN) and a conductive film 32b made of copper (Cu) is formed in a first insulating film 31 made of silicon dioxide (SiO₂) and formed on a substrate (not shown) made of Si. On the first insulating film 31, a second insulating film 33 made of silicon oxide containing carbon and nitrogen (SiOCN) and functioning as a metal diffusion preventing film is formed to cover the first metal interconnection 32.

In the upper surface of the second insulating film 33, a surface layer 33a in which the composition ratio of O to Si having the value calculated by dividing the atomic percent of O by that of Si is higher by 5% or more than in the inner portion of the second insulating film 33 is formed.

On the second insulating film 33, a third insulating film 34 made of carbon-containing silicon oxide (SiOC) with a specific dielectric constant of 3 or less and a fourth insulating film 35 made of SiO₂ are formed successively. To increase the adherence between the third and fourth insulating films 34 and 35, an extremely thin SiOC layer having a high abundance ratio of O may also be provided appropriately at the interface between the third and fourth insulating films 34 and 35.

In each of the third and fourth insulating films 34 and 35, a second metal interconnection 36 composed of a barrier metal 36a made of TaN and a conductive film 36b made of Cu is formed. The first and second metal interconnections 32 and 36 are electrically connected to each other through a via 37 extending through the second and third insulating films 33 and 34.

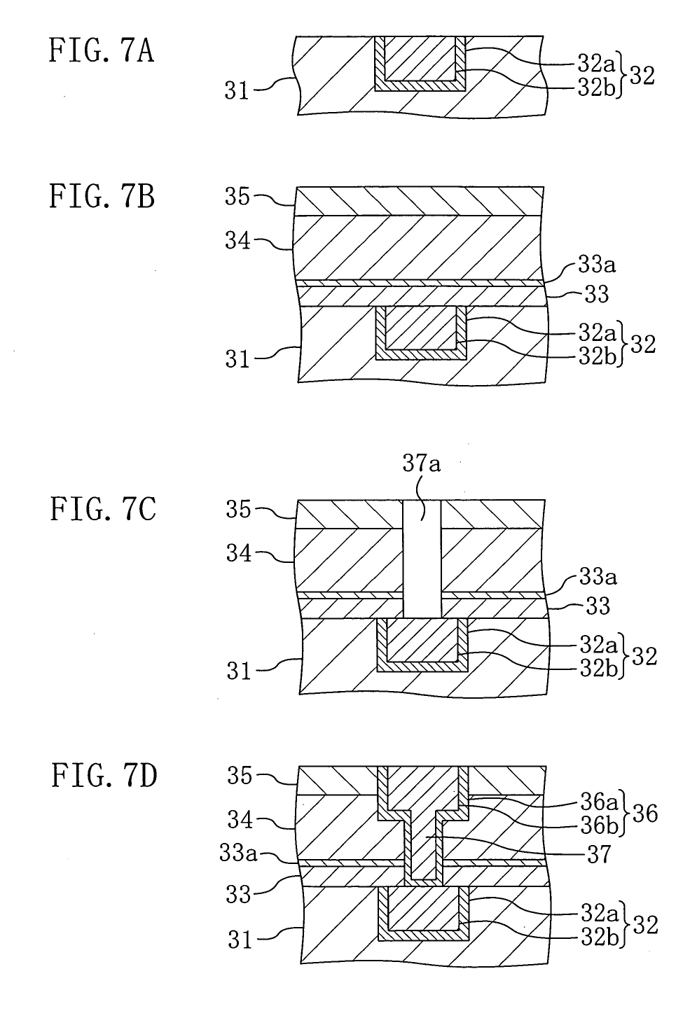

A description will be given next to a method for fabricating the semiconductor device according to the present variation. FIGS. 7A to 7D illustrate the cross-sectional states of the interconnection portions in the semiconductor device according to the present variation in the individual fabrication steps in the order they are performed;

First, as shown in FIG. 7A, the first insulating film 31 made of SiO₂ is formed on the substrate (not shown) and coated with a resist, which is formed into a pattern for an interconnection trench by lithography. Then, after forming the interconnection trench by dry etching using the pattern as a mask, the resist is removed by ashing so that the interconnection trench is formed in the first insulating film 31. Subsequently, the barrier metal 32a made of TaN is formed by sputtering in the interconnection trench and the conductive film 32b made of Cu is filled therein by electric plating. Thereafter, the unneeded portions of the barrier metal 32a and the conductive film 32b which are protruding out of the interconnection trench are removed by chemical mechanical polishing (CMP) so that the first metal interconnection 32 composed of the barrier metal 32a and the conductive film 32b is formed.

Next, as shown in FIG. 7B, the second insulating film 33 made of SiOCN is formed by CVD on the first insulating film 31 to cover the first metal interconnection 32. After the formation of the second insulating film 33, the surface of the second insulating film 33 is exposed to a plasma atmosphere using a helium (He) gas, whereby the surface of the second insulating film 33 is modified and the surface layer 33a in which the composition ratio of O to Si is higher than in the inner portion of the second insulating film 33 is formed.

After forming the surface layer 33a by modifying the surface of the second insulating film 33, the third insulating film 34 made of SiOC with a specific dielectric constant of 3 or less is formed by CVD on the second insulating film 33. Subsequently, the fourth insulating film 35 made of a SiO film is formed also by CVD on the third insulating film 34. By exposing the surface of the third insulating film 34 to a plasma atmosphere using gas containing, e.g., O and then depositing the fourth insulating film 35, the adherence between the third and fourth insulating films 34 and 35 can be increased.

Then, as shown in FIG. 7C, a resist is coated on the fourth insulating film 35 and formed into a pattern for a via hole by lithography. Thereafter, dry etching and ashing are performed by using the pattern as a mask to form a via hole 37a extending through the second, third, and fourth insulating films 33, 34, and 35.

Next, as shown in FIG. 7D, a resist is coated again on the surface of the fourth insulating film 35 and formed into a pattern for an interconnection trench by lithography. Then, by using the pattern as a mask, dry etching and ashing are performed to form the interconnection trench in each of the third and fourth insulating films 34 and 35. Thereafter, the barrier metal 36a made of TaN is formed by sputtering in the interconnection trench and then the conductive film 36b made of Cu is formed by electric plating. Subsequently the unneeded portions of the barrier metal 36a and the conductive film 36b which are protruding out of the interconnection trench are removed by CMP so that the second metal interconnection 36 composed of the barrier metal 36a and the conductive film 36b and the via 37 are formed.

As described above, the present invention allows the implementation of a high-reliability semiconductor device having metal interconnections each covered with a low dielectric constant film, wherein the low dielectric constant film has increased adherence to a metal diffusion preventing film for preventing metal diffusion from the metal interconnections at the interface therebetween and the delamination of the low dielectric constant film from the metal diffusion preventing film is less likely to occur, and a method for fabricating the same. Therefore, the present invention is useful when applied to a semiconductor device comprising metal interconnections made of copper or the like and an interlayer insulating film with a low dielectric constant, a fabrication method therefor, and the like.

What is claimed is:

1. A semiconductor device comprising:
a first insulating film formed on a substrate and having a first trenched portion;
a second insulating film formed on the first insulating film;
a third insulating film formed on the second insulating film and having a specific dielectric constant of 3 or less; and
a first interconnection formed in the first trenched portion, wherein
the second insulating film is made of a compound containing silicon, oxygen, carbon, and nitrogen and
a composition ratio of oxygen to silicon is higher by 5% or more in an upper surface of the second insulating film than in a bottom surface of the second insulating film.

2. The semiconductor device of claim 1, further comprising:
a fourth insulating film formed between the first and second insulating films and made of a compound containing silicon, oxygen, carbon, and nitrogen, wherein
the second insulating film is made of a compound in which an atomic percent of oxygen is higher than an atomic percent of nitrogen and
the fourth insulating film is made of a compound in which the atomic percent of oxygen is lower than the atomic percent of nitrogen.

3. The semiconductor device of claim 1, wherein the third insulating film is made of carbon-containing silicon oxide (SiOC).

4. The semiconductor device of claim 1, further comprising:
a second interconnection made of a conductive material filled in a second trenched portion provided in the third insulating film.

5. The semiconductor device of claim 4, further comprising:
a plug formed to extend through at least the second and third insulating films and provide an electric connection between the first and second interconnections.

6. The semiconductor device of claim 1, further comprising:
a fifth insulating film formed on the third insulating film and protecting the third insulating film.

7. A method for fabricating a semiconductor device, the method comprising the steps of:
(a) forming a first insulating film on a substrate, forming a first trenched portion in the first insulating film, and then filling a conductive material in the first trenched portion to form a first interconnection;
(b) forming, on the first insulating film, a second insulating film made of a compound containing silicon, oxygen, carbon, and nitrogen and covering the first interconnection;
(c) forming, in an upper surface of the second insulating film, a surface layer in which a composition ratio of oxygen to silicon is higher by 5% or more than in a bottom surface of the second insulating film; and
(d) forming, on the second insulating film, a third insulating film having a specific dielectric constant of 3 or less.

8. The method of claim 7, wherein the third insulating film is made of carbon-containing silicon oxide (SiOC).

9. The method of claim 7, wherein the step (c) is a step of exposing the upper surface of the second insulating film to a plasma of a helium gas or a gas mixture containing helium.

10. The method of claim 9, wherein the plasma is a plasma of a gas mixture containing at least one of oxygen and carbon dioxide.

11. The method of claim 9, wherein the step (c) is a step of continuously processing the second insulating film without exposing the second insulating film to an ambient atmosphere by using the same chamber as used to form the second insulating film in the step (b).

12. The method of claim 7, wherein the step (c) is a step of depositing, on the upper surface of the second insulating film, the surface layer in which the composition ratio of oxygen to silicon is higher by 5% or more than in the bottom surface of the second insulating film.

13. The method of claim 7, further comprising the step of:
(e) prior to the step (b), forming a fourth insulating film made of a compound containing silicon, oxygen, carbon, and nitrogen on the first insulating film, wherein
the second insulating film is made of a compound in which an atomic percent of oxygen is higher than an atomic percent of nitrogen and
the fourth insulating film is made of a compound in which the atomic percent of oxygen is lower than the atomic percent of nitrogen.

14. The method of claim 13, wherein the steps (e) and (b) are performed continuously in the same vacuum chamber.

15. The method of claim 7, further comprising the step of:
(f) after the step (d), forming a second trenched portion in an upper portion of the third insulating film and filling a conductive material in the second trenched portion to form a second interconnection.

16. The method of claim 15, wherein the step (f) includes the steps of:
forming a via hole at a position included in a region of the third insulating film formed with the second trenched portion to expose the first interconnection therethrough; and
filling a conductive material in the via hole to form a plug for providing an electric connection between the first and second interconnections.
